(19) United States
(12) Patent Application Publication
(10) Pub. No.: US 2024/0201282 A1
(43) Pub. Date: Jun. 20, 2024

(54) METHODS AND APPARATUS TO DETECT PARASITIC RESISTANCES USING DRIVER CIRCUITRY

(71) Applicant: Texas Instruments Incorporated, Dallas, TX (US)

(72) Inventors: Anand Hariraj Udupa, Bengaluru (IN); Aravind Miriyala, Bengaluru (IN); Raja Reddy Patukuri, Bengaluru (IN); Harshit Reddy Lingireddy, Hyderabad (IN)

(21) Appl. No.: 18/228,479

(22) Filed: Jul. 31, 2023

(30) Foreign Application Priority Data
Dec. 14, 2022 (IN) 202241072188

(51) Int. Cl. G01R 31/52; H03K 5/24

(52) U.S. Cl. CPC G01R 31/52; H03K 5/24

(57) ABSTRACT

An example apparatus includes: a first switch having a control terminal; a second switch having a first terminal and a control terminal; detection circuitry having a first terminal and a second terminal the detection circuitry configured to detect a parasitic resistance at the first terminal of the second switch; and controller circuitry having a first terminal and a second terminal, the first terminal of the controller circuitry coupled to the control terminal of the first switch and the control terminal of the second switch, the second terminal of the controller circuitry coupled to second terminal of the detection circuitry, the controller circuitry configured to disable the first switch responsive to the detection of the parasitic resistance.

### CROSS-REFERENCE TO RELATED APPLICATION

This patent application claims the benefit of and priority to IN Provisional Patent Application Serial No. 202241072188 filed Dec. 14, 2022, which is hereby incorporated herein by reference in its entirety.

### TECHNICAL FIELD

This description relates generally to driver circuitry and, more particularly, to methods and apparatus to detect parasitic resistances using driver circuitry.

### BACKGROUND

A light emitting diode (LED) is an electrical component capable of emitting light. An LED emits light responsive to being forward biased and a current flowing through the LED. Designers use driver circuitry to forward bias and source a current through LEDs. In some devices, driver circuitry allow LEDs to be utilized as home light sources, visual indicators, absorption sensors, flashlights, cameras, backlights, displays, etc.

### SUMMARY

For methods and apparatus to detect parasitic resistances using driver circuitry, an example apparatus includes a first switch having a control terminal; a second switch having a first terminal and a control terminal; detection circuitry having a first terminal and a second terminal the detection circuitry configured to detect a parasitic resistance at the first terminal of the second switch; and controller circuitry having a first terminal and a second terminal, the first terminal of the controller circuitry coupled to the control terminal of the first switch and the control terminal of the second switch, the second terminal of the controller circuitry coupled to second terminal of the detection circuitry, the controller circuitry configured to disable the first switch responsive to the detection of the parasitic resistance.

### BRIEF DESCRIPTION OF THE DRAWINGS

FIG. 1 is a block diagram of an example watch including LED source circuitry and measurement circuitry, the LED source circuitry to use example driver circuitry to emit light that induces a current in the measurement circuitry based on characteristics of a user.

FIG. 2 is a schematic diagram of an example implementation of the LED source circuitry of FIG. 1 including example controller circuitry to disable the driver circuitry of FIG. 1 responsive to example detection circuitry detecting a parasitic resistance.

FIG. 3 is a schematic diagram of an example implementation of detection circuitry of FIG. 2.

FIG. 4 is a schematic diagram of an example implementation of the controller circuitry of FIG. 2.

FIG. 5 is a timing diagram of an example operation of the driver circuitry of FIGS. 1 and 2.

FIG. 6 is a schematic diagram of another implementation of the example driver circuitry of FIGS. 1 and 2 to supply power to a plurality of LEDs.

FIG. 7 is a flowchart representative of example machine readable instructions and/or example operations that may be executed, instantiated, and/or performed to implement the driver circuitry of FIGS. 1, 2, and/or 6.

FIG. 8 is a block diagram of an example processing platform including programmable circuitry structured to execute, instantiate, and/or perform the example machine readable instructions and/or perform the example operations of FIG. 7 to implement the controller circuitries of FIGS. 2, 4, and/or 6.

FIG. 9 is a block diagram of an example implementation of the programmable circuitry of FIG. 8.

FIG. 10 is a block diagram of another example implementation of the programmable circuitry of FIG. 8.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

A light emitting diode (LED) is an electrical component capable of emitting light. An LED emits light responsive to being forward biased and a current flowing through the LED. Designers typically use driver circuitry to forward bias and source a current through LEDs. In some devices, driver circuitry allow LEDs to be utilized as home light sources, visual indicators, absorption sensors, flashlights, cameras, backlights, displays, etc. As LEDs become increasingly common and popular, incentives for designers to design efficient driver circuitry to drive LEDs have greatly increased.

Some driver circuitry sequences usage of LEDs to limit power consumption. In some devices, the LEDs are controlled to emit light for short pulses. The driver circuitry sequences the LEDs to save power and/or individually power one of the LEDs at a time. Driver circuitry may utilize one or more switches to sequence the LEDs. The LEDs emit light responsive to the one or more switches coupling a current source to one or more of the LEDs.

However, a parasitic resistance may be present or may arise in the circuitry coupled to the LED. A parasitic resistance is an effective resistance that is not a part of the design of the circuitry but may result from changes in the circuitry over time or due to one or more faults in the circuitry and that may lead to an improper function of the circuitry. As an example, a parasitic resistance may result from an unintended coupling of the circuitry to a common potential (e.g., ground). For example, over time, one or more faults in a printed circuit board (PCB) on which the LED and the LED driver circuitry are coupled (e.g., mounted) may result in a formation of a current path from the LED and/or LED driver circuitry to a common potential (e.g., ground) of the PCB. In some instances, the current path resulting from the one or more faults in the PCB are described and/or illustrated as a parasitic resistance coupled between the LED and the common potential. In such instances, the LED may continuously emit light due to the parasitic resistance creating the current path through the LED. The creation of such a current path by the parasitic resistance prevents the driver circuitry from sequencing usage of the LED to short pulses. Instead, the additional current path results in excessive power consumption because the LED coupled to the parasitic resistance continuously emits light. Further, a temperature of the LED increases as the LED continuously consumes power to emit light. The increasing temperature of the LED may result in permanent damage to the LED and, in devices where a user may come in contact with the LED light, result in discomfort or even harm to users.

Examples described herein include methods and apparatus to detect parasitic resistances using driver circuitry. In some described examples, an LED emits light responsive to the driver circuitry forward biasing the LED and sourcing a current through the LED when a parasitic resistance is not present. However, upon detection of a formation of a parasitic resistance coupled to the LED, the driver circuitry acts to prevent the LED from consuming power and continuously emitting light. Advantageously, the driver circuitry decreases power consumption responsive to the formation of the parasitic resistance.

In some described examples, the LED driver circuitry includes a first example switch, a second example switch, example controller circuitry, and example detection circuitry. The first switch couples a reference voltage to an anode of the LED, while the second switch couples current source circuitry to a cathode of the LED. In such a configuration, the first and second switches forward bias the LED and source a current through the LED. The controller circuitry controls the switches to determine when the LED is to emit light. The detection circuitry is coupled to the second switch to detect the formation of the parasitic resistance between the cathode of the LED and a common potential.

The detection circuitry pulls up the second switch, responsive to the LED being off (e.g., not emitting light), to detect the presence of the parasitic resistance. The detection circuitry pulls up the second switch by supplying a current and a supply voltage. When the parasitic resistance is not present, the supply current pulls a voltage of the second switch to be approximately equal to the supply voltage. In such an example, the detection circuitry successfully pulls the voltage of the second switch to the supply voltage. When the parasitic resistance is present, the parasitic resistance provides a path for the supply current to a common potential. In such examples, the supply current and the parasitic resistance create a voltage difference less than the supply voltage. Accordingly, the parasitic resistance prevents the detection circuitry from successfully pulling up the voltage of the second switch to the supply voltage. The controller circuitry prevents the switches from forward biasing the LED and sourcing a current through the LED responsive to the detection circuitry detecting the parasitic resistance. Advantageously, the driver circuitry decreases excessive power consumption by an LED responsive to parasitic resistances.

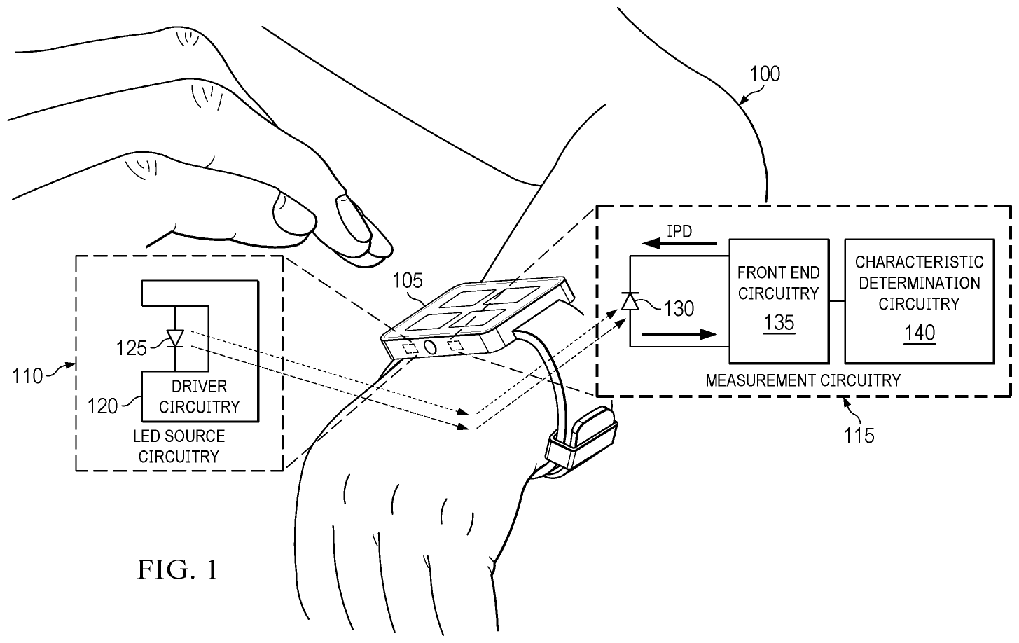

FIG. 1 is a block diagram of an example user 100 wearing an example watch 105 including example LED source circuitry 110 and example measurement circuitry 115. The user 100 is physically coupled to (e.g., wearing) the watch 105. The watch 105 determines characteristics (e.g., blood oxygen level, heart rate, etc.) of the user 100 using the LED source circuitry 110 and the measurement circuitry 115. In the example of FIG. 1, the LED source circuitry 110 and the measurement circuitry 115 are implemented in the watch 105. However, alternative applications and/or implementations of the LED source circuitry 110 and the measurement circuitry 115 may be used consistent with the described teachings.

The LED source circuitry 110 is optically coupled to the measurement circuitry 115 through the user 100. In the example of FIG. 1, the LED source circuitry 110 includes example driver circuitry 120 and an example LED 125. The LED source circuitry 110 emits light of at least one wavelength onto the user 100. In the example of FIG. 1, the measurement circuitry 115 includes an example photodiode 130, example front end circuitry 135, and example characteristic determination circuitry 140. The measurement circuitry 115 detects the light from the LED source circuitry 110 reflected through the user 100. The measurement circuitry 115 determines characteristics of the user 100 based on and/or responsive to characteristics of the detected light.

In an example operation, light emitted by an LED of the LED source circuitry 110 traverses a portion of the user 100 (e.g., the skin) towards the measurement circuitry 115. Characteristics of the user 100 modify the light from the LED source circuitry 110. For example, some light is lost to absorption. The measurement circuitry 115 detects the modified light and determines the characteristics of the user 100 based on the detective light being detected. In the example of FIG. 1, the user 100 may be considered a medium in which light from the LED source circuitry 110 traverses. Alternatively, the LED source circuitry 110 and the measurement circuitry 115 may be modified consistent with the described teachings described to emit and/or receive light through alternative and/or a plurality of mediums. In such alternative examples, the measurement circuitry 115 may be modified to determine alternative characteristics/properties of the alternative and/or the plurality of mediums.

The LED driver circuitry 120 has a first terminal coupled to an anode the LED 125. The driver circuitry 120 has a second terminal coupled to a cathode the LED 125. The driver circuitry 120 supplies an LED supply voltage (V_{LED}) to the LED 125 and sources current through the LED 125 to drive the LED. The LED 125 emits light responsive to the driver circuitry 120 supplying the LED supply voltage and sourcing the current through the LED 125.

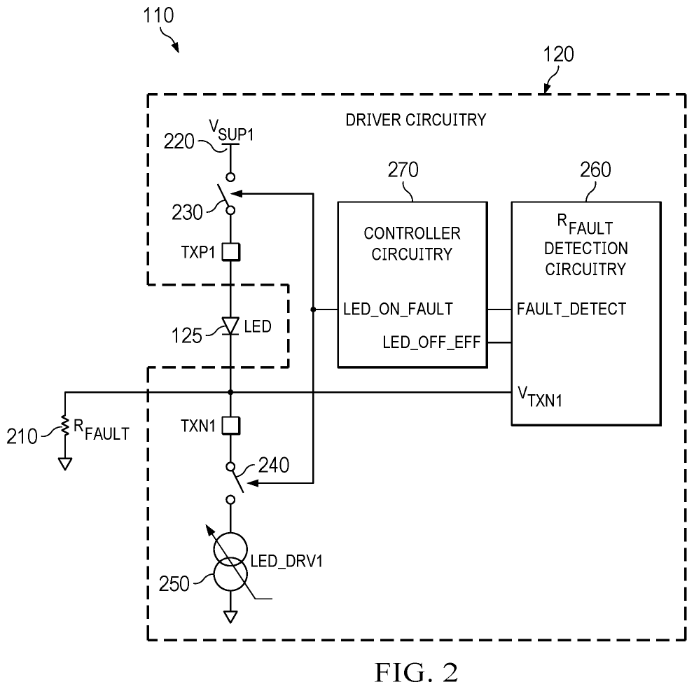

In some examples, the driver circuitry 120 determines, when the LED 125 is not emitting light (e.g., when the LED is not being driven), that a parasitic resistance (illustrated and described in connection with FIG. 2) is present and/or has formed. In some examples, the parasitic resistance forms responsive to printed circuit board (PCB) faults creating a current path to a common potential (e.g., ground). In such examples, the amount of the parasitic resistance corresponds to characteristics of a material of the PCB. The driver circuitry 120 disables (e.g., no longer drives) the LED 125 responsive to determining that a parasitic resistance is present. Advantageously, the driver circuitry 120 disables the LED 125 to reduce power loss resulting from parasitic resistances. Advantageously, disabling the LED 125 prevents the LED from continuously emitting light responsive to the parasitic resistance. In such examples, the driver circuitry 120 prevents the LED 125 from generating heat capable of harming the user 100.

The LED 125 has a first terminal (e.g., anode) coupled to the driver circuitry 120. The LED 125 has a second terminal (e.g., cathode) coupled to the driver circuitry 120. The LED 125 is optically coupled to the measurement circuitry 115. The LED 125 emits light of a wavelength responsive to the LED supply voltage and a current being sourced by the driver circuitry 120. In some examples, the LED 125 emits green light. In other examples, the LED 125 may emit one of red light, blue light, inferred light, etc.

The photodiode 130 has a first terminal (e.g., anode) coupled to the front end circuitry 135. The photodiode 130 has a second terminal (e.g., cathode) coupled to the front end circuitry 135. The photodiode 130 is optically coupled to the LED source circuitry 110. The photodiode 130 detects light emitted by the LED 125 through (e.g., reflected by) the user 100. The photodiode 130 generates a detection current (IPD) responsive to a detection of light from the LED 125. A magnitude of the detection current varies based on an intensity of the light detected by the photodiode 130. In some examples, characteristics of the user 100 result in relatively high amounts of light absorption, which reduces an amount of light detected by the photodiode 130. Such an increase in light absorption may correspond to variations in blood oxygen levels, a pulse of a heartbeat, etc. In such examples, the reduction in the amount of light reduces the magnitude of the detection current generated by the photodiode 130. The photodiode 130 supplies the detection current to the front end circuitry 135.

The front end circuitry 135 has a first terminal coupled to the anode of the photodiode 130. The front end circuitry 135 has a second terminal coupled to the cathode of the photodiode 130. The front end circuitry 135 has a third terminal coupled to the characteristic determination circuitry 140. The front end circuitry 135 determines a magnitude of the detection current of the photodiode 130. In some examples, the front end circuitry 135 may utilize an instrumentation amplifier (not illustrated) to determine the magnitude of the detection current. In such examples, an analog-to-digital converter (ADC) may convert an output of the instrumentation amplifier to a digital value representative of the magnitude of the detection current. The front end circuitry 135 supplies a value representative of the magnitude of the detection current to the characteristic determination circuitry 140.

The characteristic determination circuitry 140 has a terminal coupled to the front end circuitry 135. The characteristic determination circuitry 140 receives the value representative of the magnitude of the detection current through the photodiode 130 from the front end circuitry 135. The characteristic determination circuitry 140 monitors the detection current over time. The characteristic determination circuitry 140 determines characteristics of the user 100 based on the detection current over time. In some examples, the characteristic determination circuitry 40 uses the detection current induced by green light for heart rate monitoring. In other examples, the characteristic determination circuitry 140 uses the detection currents induced by red and inferred lights for blood oxygen monitoring. Alternatively, the characteristic determination circuitry may be used to determine alternative characteristics of the user 100.

FIG. 2 is a schematic diagram of an example implementation of the LED source circuitry 110 of FIG. 1, including the driver circuitry 120 of FIG. 1 and the LED 125 of FIG. 1. In the example of FIG. 2, the LED source circuitry 110 has, and/or is coupled to, a parasitic resistance (R_{FAULT}) 210. The LED source circuitry 110 is adaptive to be optically coupled to the measurement circuitry 115 of FIG. 1.

The driver circuitry 120 is coupled to the LED 125 and the parasitic resistance 210. In the example of FIG. 2, the driver circuitry 120 includes an example voltage supply terminal 220 that receives a supply voltage (V_{SUP1}), (e.g., from a voltage supply), a first example switch 230, a second example switch 240, example current source circuitry 250, example detection circuitry 260, and example controller circuitry 270. The LED 125 emits light responsive to the driver circuitry 120 supplying the supply voltage V_{SUP1} and sourcing a current through the LED 125 using the current source circuitry 250.

The parasitic resistance 210 couples a cathode terminal of the LED 125 to a common terminal that provides a common potential (e.g., ground). PCB faults may create the parasitic resistance 210 by creating a current path to the common potential through material of the PCB (not illustrated). In the example of FIG. 2, the parasitic resistance 210 is illustrated for simplicity and illustrative purposes. However, the parasitic resistance 210 may be described as a characteristic and/or property of the LED source circuitry 110 and/or the driver circuitry 120.

The voltage supply terminal 220 is coupled to the first switch 230. In an example, the supply voltage V_{SUP1} is a fixed voltage from a voltage supply or source (not illustrated). In another example, the supply voltage V_{SUP1} is adjustable by the driver circuitry 120 based on one or more parameters. The supply voltage V_{SUP1} is set to a value to forward bias the LED 125.

The first switch 230 has a first terminal coupled to the voltage supply terminal 220. The first switch 230 has a second terminal coupled to the anode of the LED 125. The first switch 230 has a control terminal coupled to the controller circuitry 270. The controller circuitry 270 controls the first switch 230 to open and close using a control signal. The first switch 230 supplies the voltage supply terminal 220 to the LED 125 when closed (e.g., conducting). The first switch 230 prevents the supply voltage V_{SUP1} from being supplied to the LED 125 when open (e.g., non-conducting).

The second switch 240 has a first terminal coupled to cathode the LED 125. The second switch 240 has a second terminal coupled to the current source circuitry 250. The second switch 240 has a control terminal coupled to the controller circuitry 270. The controller circuitry 270 controls the second switch 240 to open and close using a control signal. The second switch 240 allows the current source circuitry 250 to source a current from the LED 125 when closed. The second switch 240 prevents the current source circuitry 250 from sourcing a current through the LED 125 when open. In some examples, the switches 230 and 240 are implemented using transistor circuitry.

The current source circuitry 250 has a first terminal coupled to the second switch 240. The current source circuitry 250 has a second terminal coupled to the common terminal that supplies the common potential. The current source circuitry 250 sinks a current from the first terminal to the second terminal. In some examples, the current source circuitry 250 may be configurable current source circuitry capable of sourcing a range of currents.

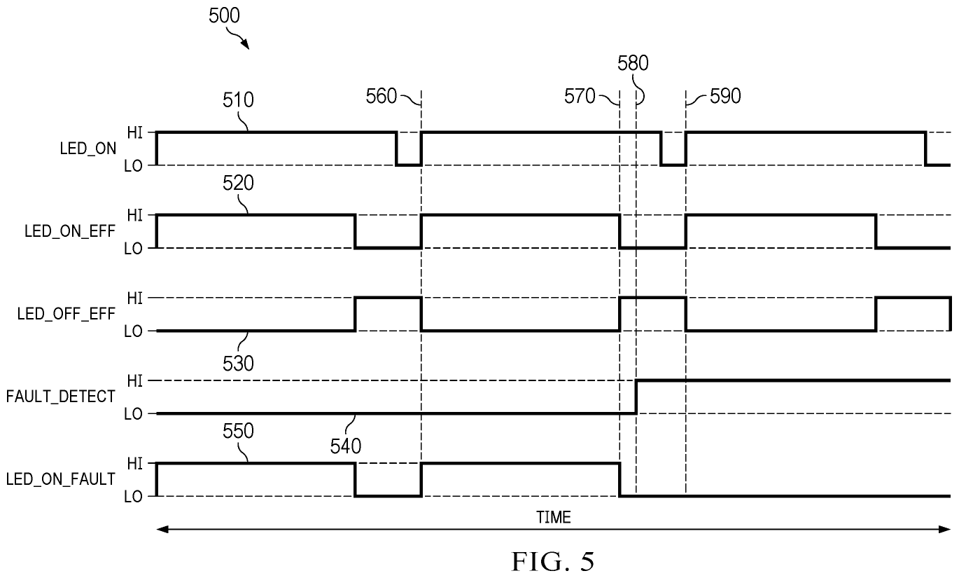

The detection circuitry 260 has a first terminal coupled to the cathode of the LED 125, to the parasitic resistance 210, and to the second switch 240. The detection circuitry 260 has a second terminal coupled to the controller circuitry 270. The detection circuitry 260 has a third terminal coupled to the controller circuitry 270. The detection circuitry 260 receives an LED off effective (LED_OFF_EFF) signal from the controller circuitry 270. The LED off effective signal represents durations of time when the LED 125 is not emitting light (e.g., off). An example of the LED off effective signal is described and illustrated in FIG. 5, below. The detection circuitry 260 supplies a fault detection (FAULT_DETECT) signal to the controller circuitry 270. The fault detection signal represents whether or not the detection circuitry 260 detects the parasitic resistance 210. An example of the fault detection signal is described and illustrated in FIG. 5, below.

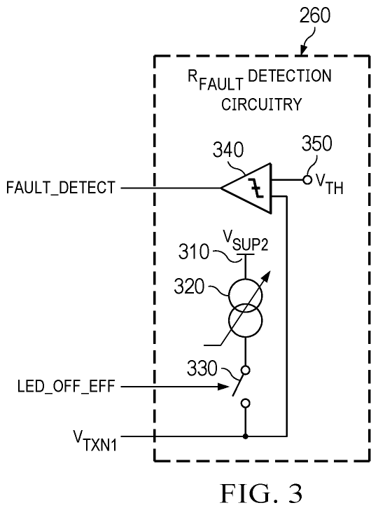

The detection circuitry 260 detects the parasitic resistance 210 based on a voltage at the first terminal of the second switch 240 (e.g., and at the cathode of the LED 125) and the LED off effective signal. In some examples, the detection circuitry 260 detects the parasitic resistance 210 responsive to pulling-up the first terminal of the second switch 240. In such an example, the detection circuitry 260 compares the voltage of the first terminal of the second switch 240 to a threshold voltage to detect the parasitic resistance 210. Such an example is described and illustrated in FIG. 3, below. The detection circuitry 260 indicates a detection of the parasitic resistance 210 by providing the fault detection signal. In some examples, the detection circuitry 260 asserts (e.g., sets to a high logic level) the fault detection signal to indicate detection of the parasitic resistance 210.

The controller circuitry 270 has a first terminal coupled to the control terminals of the switches 230 and 240. The controller circuitry 270 has a second terminal coupled to the detection circuitry 260. The controller circuitry 270 has a third terminal coupled to the detection circuitry 260. The controller circuitry 270 supplies an LED on fault signal (LED_ON_FAULT) to the switches 230 and 240. The LED on fault signal controls opening and closing the switches 230 and 240.

The controller circuitry 270 generates the LED on fault signal responsive to the fault detection signal from the detection circuitry 260 and durations that the LED 125 is to emit light. In some example, the controller circuitry 270 sets the LED on fault signal to a first logic level (e.g., a logic high or a logic low) to close the switches 230 and 240. In such examples, the controller circuitry 270 sets the LED on fault signal to a second logic level to open the switches 230 and 240. For example, the controller circuitry 270 closes the switches 230 and 240 by setting the LED on fault signal to a logic high. In the example of FIG. 2, the LED 125 emits light responsive to the controller circuitry 270 closing the switches 230 and 240. An example of the LED on fault signal is described and illustrated in FIG. 5, below.

In an example, the controller circuitry 270 generates the LED off effective signal as an inverse of the duration that the LED 125 is to emit light. For example, the controller circuitry 270 sets the LED off effective signal to a logic low responsive to the LED 125 being turned on. In some examples, the controller circuitry 270 may delay rising edges of the LED off effective signal to account for settling times of the switches 230 and 240. In such examples, the controller circuitry 270 may decrease a duty cycle of the LED off effective signal to prevent overlap with the LED on fault signal. The controller circuitry 270 supplies the LED off effective signal to the detection circuitry 260. An example of the LED off effective signal is described and illustrated in FIG. 5, below.

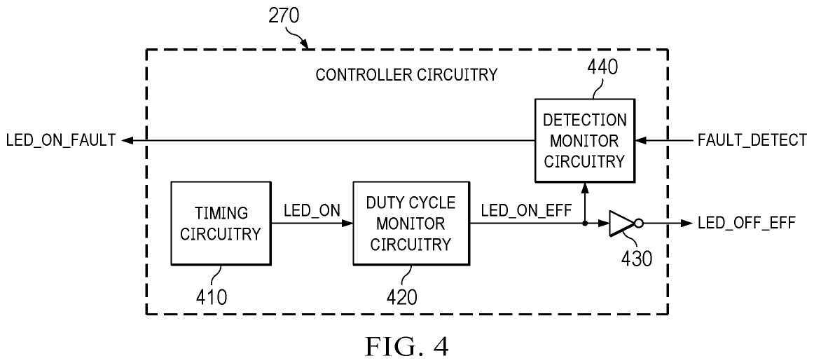

The controller circuitry 270 receives the fault detection signal from the detection circuitry 260. The controller circuitry 270 prevents the LED on fault signal from being set to a logic level that closes the switches 230 and 240 responsive to the fault detection signal. In some examples, the controller circuitry 270 prevents the LED on fault signal from changing logic states responsive to the fault detection signal being set by detection circuitry 260. In such examples, the controller circuitry 270 keeps the switches 230 and 240 open responsive to the detection circuitry 260 detecting the parasitic resistance 210. An example implementation of the controller circuitry 270 is illustrated and described in connection with FIG. 4, below.

FIG. 3 is a schematic diagram of an example implementation of detection circuitry 260 of FIG. 2. In the example of FIG. 3, the detection circuitry 260 includes an example voltage supply terminal 310 that receives a supply voltage (V_{SUP2}), (e.g., from a voltage supply), example current source circuitry 320, an example switch 330, an example comparator 340, and an example threshold voltage terminal 350 at which a threshold voltage (VTH) is provided (e.g., by the controller circuitry 270 or by some other controller or memory circuitry (not shown). The detection circuitry 260 is adaptive to be coupled to the LED 125 of FIGS. 1 and 2, the second switch 240 of FIG. 2, and the controller circuitry 270 of FIG. 2.

The voltage supply terminal 310 is coupled to the current source circuitry 320. In an example, the supply voltage V_{SUP2} is a fixed voltage from a voltage supply or source (not illustrated). In another example, the supply voltage V_{SUP2} is adjustable by the driver circuitry 120 based on one or more parameters. The supply voltage V_{SUP2} is set to a value to be a pull-up voltage of the first terminal of the second switch 240.

The current source circuitry 320 has a first terminal coupled to the voltage supply terminal 310. The current source circuitry 250 has a second terminal coupled to the switch 330. The current source circuitry 320 supplies a current from the first terminal to the second terminal. The current source circuitry 320 pulls up the first terminal of the second switch 240 towards the voltage supply terminal 310 when the switch 330 is closed and the parasitic resistance 210 is not present. In some examples, the current source circuitry 320 may be configurable current source circuitry capable of sourcing a range of currents.

The switch 330 has a first terminal coupled to current source circuitry 320. The switch 330 has a second terminal coupled to the comparator 340 and adaptive to be coupled to the LED 125, the parasitic resistance 210, and/or the second switch 240. The switch 330 has a control terminal adaptive to be coupled to the controller circuitry 270. The switch 330 receives the LED off effective signal from the controller circuitry 270. The LED off effective signal from the controller circuitry 270 controls the switch 330. The current source circuitry 320 supplies a current to the LED 125, the parasitic resistance 210, the second switch 240, and/or the comparator 340 when closed. The switch 330 prevents the current source circuitry 320 from supplying a current to the parasitic resistance 210, the second switch 240 and/or the comparator 340 when open.

The comparator 340 has a first input coupled to the switch 330 and adaptive to be coupled to the LED 125, the parasitic resistance 210, and/or the second switch 240. The comparator 340 has a second input coupled to the threshold voltage terminal 350. The comparator 340 has an output adaptive to be coupled to the controller circuitry 270. The comparator 340 compares a voltage of the first input to the threshold voltage terminal 350. In the example of FIG. 3, the voltage of the first input is approximately equal to the voltage of the first terminal of the second switch 240. In some examples, the comparator 340 determines that the voltage of the first input is greater than the threshold voltage terminal 350. In other examples, the comparator 340 determines that the voltage of the first input is less than the threshold voltage terminal 350. The comparator 340 generates the fault detection signal based on the comparison. The comparator 340 is adaptive to supply the fault detection signal to the controller circuitry 270.

The threshold voltage terminal 350 is coupled to the comparator 340 at which a threshold voltage VTH is provided. In an example, the threshold voltage VTH is a fixed voltage from a voltage supply or source such as a memory device (not illustrated). The threshold voltage VTH is configured to be less than the supply voltage V_{SUP2} and greater than the common potential. In some examples, the threshold voltage VTH is determined based on a multiplication of a current being supplied by the current source circuitry 320 and a maximum tolerable value of the parasitic resistance 210. The maximum tolerable value of the parasitic resistance 210 determines a level at which the comparator 340 detects the parasitic resistance 210. For example, a condition where the parasitic resistance 210 is not present may be represented by a parasitic resistance 210 with an infinite resistance. However, as faults in the PCB begin to allow current to flow to the common potential, the value of the parasitic resistance 210 begins to decrease.

In example operation, the controller circuitry 270 closes the switch 330 responsive to the LED 125 being off. The current source circuitry 320 may pull up the LED 125, the parasitic resistance 210, and/or the second switch 240 responsive to the switch 330 being closed. For example, the current source circuitry 320 pulls up a voltage of the second switch 240 to approximately the supply voltage at the voltage supply terminal 310 when the parasitic resistance 210 is not present. In another example, the current source circuitry 320 generates a voltage at the second switch 240, which is approximately equal to the current being supplied times the parasitic resistance 210. In such an example, the current source circuitry 320 fails to pull up the second switch 240, and the voltage at the second switch 240 indicates the presence of the parasitic resistance 210. The controller circuitry 270 opens the switch 330 in response to the LED 125 being on. The switch 330 prevents the current source circuitry 320 from pulling-up the first terminal of the second switch 240 when the LED 125 is on. In an example operation where the parasitic resistance 210 is not present (e.g., no PCB fault), the voltage of the first input of the comparator 340 is approximately equal to the voltage supply terminal 310. In such an example operation, the current source circuitry 320 pulls up the first input of the comparator 340 to the supply voltage V_{SUP2} responsive to a lack of a current path to the common potential.

In an example operation where the parasitic resistance 210 is present (as shown in FIG. 2), current from the current source circuitry 320 generates a voltage difference across the parasitic resistance 210. In such an example operation, the voltage of the first input of the comparator 340 is approximately equal to the voltage difference across the parasitic resistance 210. The comparator 340 determines the parasitic resistance 210 is present responsive to the voltage difference across the parasitic resistance 210 being less than the threshold voltage VTH at the threshold voltage terminal 350. Advantageously, the comparator 340 asserts the fault detection signal when the parasitic resistance 210 prevents the current source circuitry 320 from pulling-up the first input of the comparator 340. Advantageously, the detection circuitry 260 detects the formation of the parasitic resistance 210.

FIG. 4 is a block diagram of an example implementation of the controller circuitry 270 of FIG. 2 to control the switches 230 and 240 of FIG. 2 responsive to the detection circuitry 260 of FIGS. 2 and 3. The controller circuitry 270 of FIG. 4 may be instantiated (e.g., creating an instance of, bring into being for any length of time, materialize, implement, etc.) at least in part by programmable circuitry such as a Central Processor Unit (CPU) executing first instructions. Additionally or alternatively, the controller circuitry 270 of FIG. 4 may be instantiated (e.g., creating an instance of, bring into being for any length of time, materialize, implement, etc.) at least in part by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 4 may, thus, be instantiated at the same or different times. Some or all of the circuitry of FIG. 4 may be instantiated, for example, in one or more threads executing concurrently on hardware and/or in series on hardware. Moreover, in some examples, some or all of the circuitry of FIG. 4 may be implemented by microprocessor circuitry executing instructions and/or FPGA circuitry performing operations to implement one or more virtual machines and/or containers.

FIG. 4 is a schematic diagram of an example implementation of the controller circuitry 270 of FIG. 2. In the example of FIG. 4, the controller circuitry 270 includes example timing circuitry 410, example duty cycle monitor circuitry 420, an example inverter 430, and example detection monitor circuitry 440. The controller circuitry 270 is adaptive to be coupled to the switches 230 and 240 of FIG. 2 and the detection circuitry 260 of FIGS. 2 and 3.

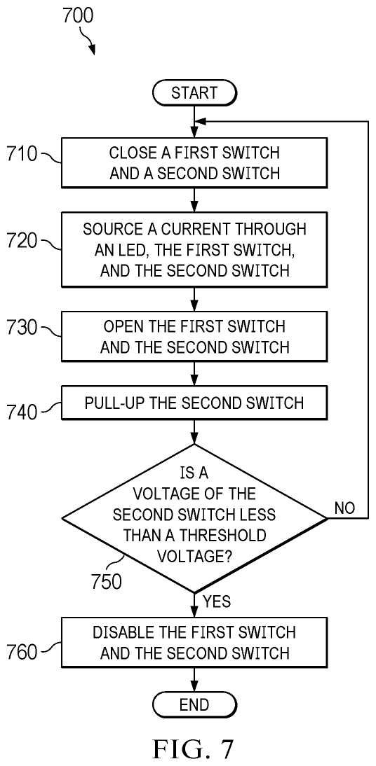

The timing circuitry 410 is coupled to the duty cycle monitor circuitry 420. The timing circuitry 410 generates an LED on signal. The LED on signal represents target timing of closing and opening the switches 230 and 240. In some examples, the timing circuitry 410 generates the LED on signal using a pulse width modulation. In such examples, the timing circuitry 410 adjusts a duty cycle of the LED on signal to configure the durations that the switches 230 and 240 are opened and closed. An example of the LED on signal is described and illustrated in FIG. 5, below. The timing circuitry 410 supplies the LED on signal to the duty cycle monitor circuitry 420. In some examples, the timing circuitry 410 is instantiated by programmable circuitry executing timing instructions and/or configured to perform operations such as those represented by the flowchart of FIG. 7.

The duty cycle monitor circuitry 420 has a first terminal coupled to the timing circuitry 410. The duty cycle monitor circuitry 420 has a second terminal coupled to the inverter 430 and the detection monitor circuitry 440. The duty cycle monitor circuitry 420 receives the LED on signal from the timing circuitry 410. The duty cycle monitor circuitry 420 generates an LED on effective signal based on the LED on signal and duty cycle constraints. The duty cycle monitor circuitry 420 monitors the duty cycle of the LED on signal. The duty cycle monitor circuitry 420 modifies the duration of time that the switches 230 and 240 are open to be greater than or equal to a minimum time. In some examples, the minimum time represents a sufficient amount of time for the detection circuitry 260 to detect the parasitic resistance 210 of FIG. 2. In such examples, the minimum time may be based on settling times of the detection circuitry 260 and/or gate delays of the circuitry included in the detection circuitry 260. In other examples, the minimum time represents a sufficient amount of time for the controller circuitry 270 to turn on additional LEDs.

In an example, the duty cycle monitor circuitry 420 decreases the duty cycle of the LED on signal to generate the LED on effective signal responsive to the duty cycle being greater than a maximum value. The maximum value may be determined based on the minimum time. An example of the LED on effective signal is described and illustrated in FIG. 5, below. The duty cycle monitor circuitry 420 supplies the LED on effective signal to the inverter 430 and the detection monitor circuitry 440. In some examples, the duty cycle monitor circuitry 420 is instantiated by programmable circuitry executing duty cycle monitor instructions and/or configured to perform operations such as those represented by the flowchart of FIG. 7.

The inverter 430 has an input coupled to the duty cycle monitor circuitry 420 and the detection monitor circuitry 440. The inverter 430 has an output adaptive to be coupled to the detection circuitry 260. The inverter 430 receives the LED on effective signal from the duty cycle monitor circuitry 420. The inverter 430 generates the LED off effective signal by inverting the LED on effective signal. In some examples, the inverter 430 adds a propagation delay to allow a voltage at the first terminal of the second switch 240 of FIG. 2 to settle. The inverter 430 supplies the LED off effective signal to the detection circuitry 260. An example of the LED off effective signal is described and illustrated in FIG. 5, below. In some examples, the inverter 430 is instantiated by programmable circuitry executing inverting instructions and/or configured to perform operations such as those represented by the flowchart of FIG. 7.

The detection monitor circuitry 440 has a first terminal coupled to the duty cycle monitor circuitry 420 and the inverter 430. The detection monitor circuitry 440 has a second terminal adaptive to be coupled to the detection circuitry 260. The detection monitor circuitry 440 has a third terminal adaptive to be coupled to the switches 230 and 240. The detection monitor circuitry 440 receives the LED on effective signal from the duty cycle monitor circuitry 420. The detection monitor circuitry 440 receives the fault detection signal from the detection circuitry 260. The detection monitor circuitry 440 generates the LED on fault signal based on the LED on effective signal and the fault detection signal. The detection monitor circuitry 440 sets the LED on fault signal approximately equal to the LED on effective signal until the detection circuitry 260 detects the parasitic resistance 210. The detection monitor circuitry 440 sets the LED on fault signal at a logic level corresponding to the switches 230 and 240 being disabled responsive to the fault detection signal representing a detection of the parasitic resistance 210. The detection monitor circuitry 440 is adaptive to supply the LED on fault signal to the switches 230 and 240. In some examples, the detection monitor circuitry 440 is instantiated by programmable circuitry executing detection monitoring instructions and/or configured to perform operations such as those represented by the flowchart of FIG. 7.

FIG. 5 is a timing diagram 500 of an example operation of the driver circuitry 120 of FIGS. 1 and 2. In the example of FIG. 5, the timing diagram 500 includes an example LED on signal (LED_ON) 510, an example LED on effective (LED_ON_EFF) signal 520, an example LED off effective (LED_OFF_EFF) signal 530, an example fault detection (FAULT_DETECT) signal 540, and an example LED on fault (LED_ON_FAULT) signal 550.

The LED on signal 510 illustrates the output of the timing circuitry 410 of FIG. 4 over time. In some examples, the timing circuitry 410 may generate the LED on signal 510 using pulse width modulation (PWM). In such examples, a duty cycle of the LED on signal 510 corresponds to times that the timing circuitry 410 attempts to turn on the LED 125 of FIGS. 1 and 2.

The LED on effective signal 520 illustrates the output of the duty cycle monitoring circuitry 420 of FIG. 4 over time. The duty cycle monitoring circuitry 420 generates the LED on effective signal 520 to be equal to the LED on signal 510 when the duty cycle of the LED on signal 510 is less than a maximum value. The LED off effective signal 530 illustrates the output of the inverter 430 of FIG. 4 over time. The inverter 430 generates the LED off effective signal 530 by inverting the LED on effective signal 520. In the example of FIG. 5, the switch 330 of FIG. 3 is open when the LED off effective signal 530 is a logic low and closed when the LED off effective signal 530 is a logic high.

The fault detection signal 540 illustrates the output of the comparator 340 of FIG. 3 over time. The comparator 340 sets the fault detection signal 540 to a logic high responsive to a detection of the parasitic resistance 210 of FIG. 2. The LED on fault signal 550 illustrates the output of the detection monitor circuitry 440 of FIG. 4. The detection monitor circuitry 440 generates the LED on fault signal 550 approximately equal to the LED on effective signal 520 when the fault detection signal 540 is a logic low. The switches 230 and 240 of FIG. 2 are closed when the LED on fault signal 550 is a logic high and open when the LED on fault signal 550 is a logic open.

At a first time 560, the parasitic resistance 210 is not coupled to the driver circuitry 120 (e.g., no PCB faults). At the first time 560, the timing circuitry 410 attempts to turn on the LED 125 of FIGS. 1 and 2 by setting the LED on signal 510. At the first time 560, the duty cycle monitor circuitry 420 sets the LED on effective signal 520 responsive to a rising edge on the LED on signal 510. At the first time 560, the inverter 430 inverts the LED on effective signal 520 to generate a falling edge on the LED off effective signal 530.

At approximately the first time 560, the falling edge of the LED off effective signal 530 opens the switch 330. At the first time 560, the detection monitor circuitry 440 determines that the fault detection signal 540 represents that the detection circuitry 260 is not detecting the parasitic resistance 210. At the first time 560, the detection monitor circuitry 440 replicates the rising edge of the LED on effective signal 520 responsive to the fault detection signal 540. At the first time 560, the switches 230 and 240 are closed responsive to the rising edge of the LED on fault signal 550.

At a second time 570, the duty cycle monitor circuitry 420 determines the duty cycle of the LED on signal 510 is greater than or equal to a maximum duty cycle. At the second time 570, the duty cycle monitor circuitry 420 sets the LED on effective signal 520 to a logic low. At the second time 570, the duty cycle monitor circuitry 420 modifies the LED on effective signal 520 to allow the detection circuitry 260 enough time to detect the parasitic resistance 210. At the second time 570, the duty cycle monitor circuitry 420 replicates the falling edge of the LED on signal 510 responsive to the duty cycle of the LED on signal 510 being less than a maximum duty cycle. At the second time 570, the inverter 430 inverts the LED on effective signal 520 to generate a rising edge on the LED off effective signal 530.

Between the times 560 and 570, the parasitic resistance 210 forms, for instance responsive to a PCB fault. At approximately the second time 570, the rising edge of the LED off effective signal 530 closes the switch 330. At approximately the second time 570, the detection monitor circuitry 440 replicates the falling edge of the LED on effective signal 520. At the second time 570, the switches 230 and 240 are opened responsive to the falling edge of the LED on fault signal 550. At approximately the second time 570, the detection circuitry 260 begins to attempt to pull-up the first terminal of the second switch 240.

At a third time 580, the comparator 340 detects a voltage responsive to the current source circuitry 320 of FIG. 3 pulling-up the first terminal of the second switch 240 is less than the threshold voltage VTH at the threshold voltage terminal 350 of FIG. 3. At the third time 580, the fault detection signal 540 has a rising edge responsive to the output of the comparator 340 representing a detection of the parasitic resistance 210.

At a fourth time 590, the timing circuitry 410 attempts to turn on the LED 125 by setting the LED on signal 510. At the fourth time 590, the duty cycle monitor circuitry 420 sets the LED on effective signal 520 responsive to a rising edge on the LED on signal 510. At the fourth time 590, the inverter 430 inverts the LED on effective signal 520 to generate a falling edge on the LED off effective signal 530.

At approximately the fourth time 590, the falling edge of the LED off effective signal 530 opens the switch 330. At the fourth time 590, the detection monitor circuitry 440 determines that the fault detection signal 540 represents that the detection circuitry 260 is detecting the parasitic resistance 210. Following the fourth time 590, the detection monitor circuitry 440 holds the LED on effective signal 520 responsive to a detection of the parasitic resistance 210 by the fault detection signal 540. Following the fourth time 590, the switches 230 and 240 remain open. Advantageously, the detection circuitry 260 reduces power consumption responsive to the formation of the parasitic resistance 210.

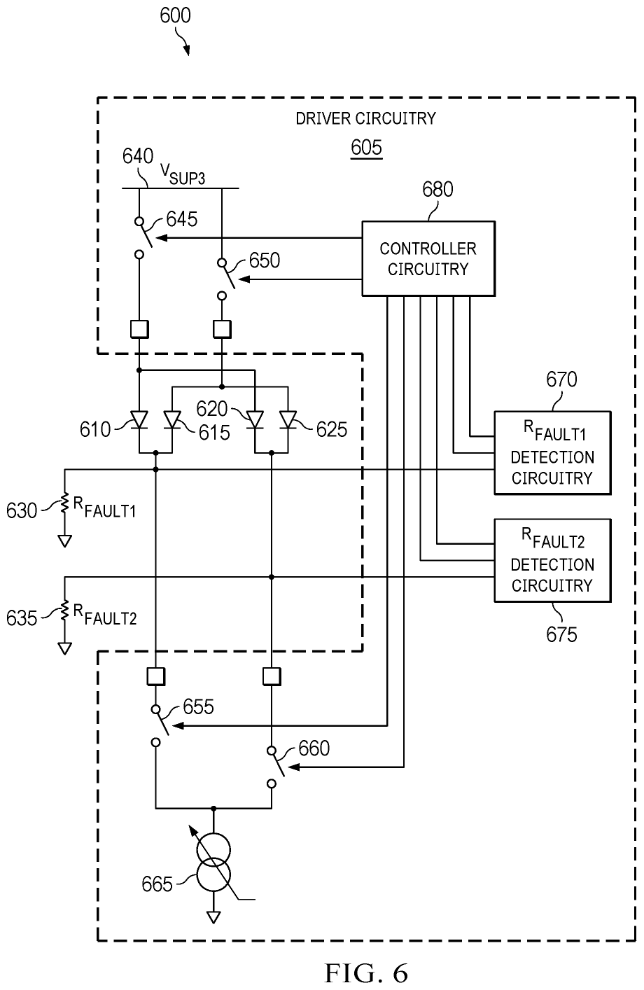

FIG. 6 is a schematic diagram of an alternative implementation of the detection circuitry 260 of FIGS. 2 and 3 in example multi-LED source circuitry 600. In the example of FIG. 6, the multi-LED source circuitry 600 includes example driver circuitry 605, a first example LED 610, a second example LED 615, a third example LED 620, and a fourth example LED 625. The multi-LED source circuitry 600 supplies power to the LEDs 610-625 by the driver circuitry 605. In the example of FIG. 6, the multi-LED source circuitry 600 has a first example parasitic resistance (R_{FAULT1}) 630 and a second example parasitic resistance (R_{FAULT2}) 635.

The driver circuitry 605 is coupled to the LEDs 610-625 and the parasitic resistances 630 and 635. In the example of FIG. 6, the driver circuitry 605 includes an example voltage supply terminal 640 that receives a supply voltage (V_{SUP3}), (e.g., from a voltage supply), a first example switch 645, a second example switch 650, a third example switch 655, a fourth example switch 660, example current source circuitry 665, first example detection circuitry 670, second example detection circuitry 675, and example controller circuitry 680. The driver circuitry 605 supplies power to the LEDs 610-625. At least one of the LEDs 610-625 emits light responsive to the driver circuitry 605 supplying power to the at least one of the LEDs 610-625.

The first LED 610 has a first terminal coupled to the driver circuitry 605. The first LED 610 has a second terminal coupled to the driver circuitry 605 and/or the first parasitic resistance 630. The first LED 610 emits light responsive to the driver circuitry 605 forward biasing and sourcing a current through the first LED 610.

The second LED 615 has a first terminal coupled to the driver circuitry 605. The second LED 615 has a second terminal coupled to the driver circuitry 605 and/or the first parasitic resistance 630. The second LED 615 emits light responsive to the driver circuitry 605 forward biasing and sourcing a current through the second LED 615.

The third LED 620 has a first terminal coupled to the driver circuitry 605. The third LED 620 has a second terminal coupled to the driver circuitry 605 and/or the second parasitic resistance 635. The third LED 620 emits light responsive to the driver circuitry 605 forward biasing and sourcing a current through the third LED 620.

The fourth LED 625 has a first terminal coupled to the driver circuitry 605. The fourth LED 625 has a second terminal coupled to the driver circuitry 605 and the second parasitic resistance 635. The fourth LED 625 emits light responsive to the driver circuitry 605 forward biasing and sourcing a current through the fourth LED 625.

The first parasitic resistance 630 couples to the LEDs 610 and 615 to the common terminal that provides the common potential. PCB faults create the first parasitic resistance 630 responsive to creating a current path to the common potential through the PCB (not illustrated).

The second parasitic resistance 635 couples the LEDs 620 and 625 to the common terminal that provides the common potential. PCB faults create the second parasitic resistance 635 responsive to creating a current path to the common potential. In the example of FIG. 6, the parasitic resistances 630 and 635 are illustrated for simplicity and illustrative purposes. However, the parasitic resistances 630 and 635 may be described as a characteristic and/or property of the driver circuitry 605.

The voltage supply terminal 640 is coupled to the switches 645 and 650. In an example, the voltage supply terminal 640 provides a fixed supply voltage V_{SUP3} from a voltage supply or source (not illustrated). In another example, the supply voltage V_{SUP3} is adjustable by the driver circuitry 605 based on one or more parameters. The supply voltage at the voltage supply terminal 640 is set to a voltage to forward bias the LEDs 610-625.

The first switch 645 has a first terminal coupled to the voltage supply terminal 640. The first switch 645 has a second terminal coupled to the LEDs 610 and 620. The first switch 645 has a control terminal coupled to the controller circuitry 680. The controller circuitry 680 controls the first switch 645 to open and close using a control signal. The first switch 645 supplies the supply voltage at the voltage supply terminal 640 to the LEDs 610 and 620 when closed. The controller circuitry 680 prevents the first switch 645 from supplying the supply voltage at the voltage supply terminal 640 to the LEDs 610 and 620 when open.

The second switch 650 has a first terminal coupled to the voltage supply terminal 640. The second switch 650 has a second terminal coupled to the LEDs 615 and 625. The second switch 650 has a control terminal coupled to the controller circuitry 680. The controller circuitry 680 controls the second switch 650 to open and close using a control signal. The second switch 650 supplies the supply voltage at the voltage supply terminal 640 to the LEDs 615 and 625 when closed. The controller circuitry 680 prevents the second switch 650 from supplying the supply voltage at the voltage supply terminal 640 to the LEDs 615 and 625 when open.

The third switch 655 has a first terminal coupled to the LEDs 610 and 615. The third switch 655 has a second terminal coupled to the current source circuitry 665. The third switch 655 has a control terminal coupled to the controller circuitry 680. The controller circuitry 680 controls the third switch 655 to open and close using a control signal. The third switch 655 allows the current source circuitry 665 to source a current from the LEDs 610 and 615 when closed. The third switch 655 prevents the current source circuitry 665 from sourcing a current through the LEDs 610 and 615 when open.

The fourth switch 660 has a first terminal coupled to the LEDs 620 and 625. The fourth switch 660 has a second terminal coupled to the current source circuitry 665. The fourth switch 660 has a control terminal coupled to the controller circuitry 680. The controller circuitry 680 controls the fourth switch 660 to open and close using a control signal. The fourth switch 660 allows the current source circuitry 665 to source a current from the LEDs 620 and 625 when closed. The fourth switch 660 prevents the current source circuitry 665 from sourcing a current through the LEDs 620 and 625 when open.

The current source circuitry 665 has a first terminal coupled to the switches 655 and 660. The current source circuitry 665 has a second terminal coupled to the common terminal that supplies the common potential. The current source circuitry 665 sinks a current from the first terminal to the second terminal. In some examples, the current source circuitry 665 may be configurable current source circuitry capable of sourcing a range of currents.

The first detection circuitry 670 has a first terminal coupled to the LEDs 610 and 615, the first parasitic resistance 630, and the third switch 655. The first detection circuitry 670 has a second terminal coupled to the controller circuitry 680. The first detection circuitry 670 has a third terminal coupled to the controller circuitry 680. The first detection circuitry 670 receives a first LED off effective signal from the controller circuitry 680. The first LED off effective signal represents durations of time when the LEDs 610 and 615 are not emitting light (e.g., off). The first LED off effective signal is similar to the LED off effective signal 530 described and illustrated in FIGS. 2 and 5, above. The first detection circuitry 670 supplies a first fault detection signal to the controller circuitry 680. The first fault detection signal represents whether or not the first detection circuitry 670 detects the first parasitic resistance 630. The first fault detection signal is similar to the fault detection signal 540 described and illustrated in FIGS. 2 and 5, above.

The second detection circuitry 675 has a first terminal coupled to the LEDs 620 and 625, the second parasitic resistance 635, and the fourth switch 660. The second detection circuitry 675 has a second terminal coupled to the controller circuitry 680. The second detection circuitry 675 has a third terminal coupled to the controller circuitry 680. The second detection circuitry 675 receives a second LED off effective signal from the controller circuitry 680. The second LED off effective signal represents durations of time when the LEDs 620 and 625 are not emitting light (e.g., off). The second LED off effective signal is similar to the LED off effective signal 530 described and illustrated in FIGS. 2 and 5, above. The second detection circuitry 675 supplies a second fault detection signal to the controller circuitry 680. The second fault detection signal represents whether or not the second detection circuitry 675 detects the second parasitic resistance 635. The second fault detection signal is similar to the fault detection signal 540 described and illustrated in FIGS. 2 and 5, above.

The detection circuitries 670 and 675 detect the parasitic resistances 630 and/or 635 based on voltages of the first terminals of the switches 655 and 660 and the LED off effective signals. In some examples, the detection circuitries 670 and/or 675 detect the parasitic resistances 630 and/or 635 responsive to pulling-up the first terminal of the switches 655 and 660. In such an example, the detection circuitries 670 and 675 compare the voltages of the first terminal of the switches 655 and 660 to a threshold voltage to detect the parasitic resistances 630 and/or 635. A similar example is described and illustrated in FIG. 3, above. The detection circuitries 670 and 675 indicate a detection of the parasitic resistances 630 and/or 635 by the fault detection signals. In some examples, the detection circuitries 670 and/or 675 assert (e.g., sets to a high logic level) at least one of the fault detection signals.

The controller circuitry 680 has a first terminal coupled to the first switch 645. The controller circuitry 680 has a second terminal coupled to the second switch 650. The controller circuitry 680 has a third terminal coupled to the third switch 655. The controller circuitry 680 has a fourth terminal coupled to the fourth switch 660. The controller circuitry 680 has a fifth terminal coupled to the first detection circuitry 670. The controller circuitry 680 has a sixth terminal coupled to the first detection circuitry 670. The controller circuitry 680 has a seventh terminal coupled to the second detection circuitry 675. The controller circuitry 680 has an eighth terminal coupled to the second detection circuitry 675. In some examples, the controller circuitry 680 is instantiated by programmable circuitry executing controller instructions and/or configured to perform operations such as those represented by the flowchart of FIG. 7.

The controller circuitry 680 supplies a first LED on fault signal to the first switch 645. The controller circuitry 680 supplies a second LED on fault signal to the second switch 650. The controller circuitry 680 supplies a third LED on fault signal to the third switch 655. The controller circuitry 680 supplies a fourth LED on fault signal to the fourth switch 660. The LED on fault signals control the switches 645-660. The LED on fault signals of FIG. 6 are similar to the LED on fault signal 550 described and illustrated in FIGS. 2 and 5, above.

The controller circuitry 680 generates the first LED on fault signal based on the fault detection signals from the detection circuitries 670 and 675 and durations that the LEDs 610 and/or 620 are to emit light. The controller circuitry 680 sets the first LED on fault signal to disable one of the LEDs 610 and/or 620 responsive to at least one of the fault detection signals indicating a detection of one of the parasitic resistances 630 and/or 635. For example, the controller circuitry 680 allows the first LED on fault signal to close the first switch 645 for durations where the third LED 620 emits light despite disabling the first LED 610. In such an example, the first detection circuitry 670 detects the first parasitic resistance 630 and the second detection circuitry 675 does not detect the second parasitic resistance 635 (e.g., the second parasitic resistance 635 is not present). Advantageously, the controller circuitry 680 disables the first switch 645 based on an individual detection of either of the parasitic resistances 630 and 635. Advantageously, the first LED 610 may continue to emit light despite the second parasitic resistance 635 being present. Advantageously, the third LED 620 may continue to emit light despite the first parasitic resistance 630 being present.

The controller circuitry 680 generates the second LED on fault signal based on the fault detection signals from the detection circuitries 670 and 675 and durations that the LEDs 615 and/or 625 are to emit light. The controller circuitry 680 sets the second LED on fault signal to disable one of the LEDs 615 and/or 625 responsive to at least one of the fault detection signals indicating a detection of one of the parasitic resistances 630 and/or 635. For example, the controller circuitry 680 allows the second LED on fault signal to close the second switch 650 for durations where the second LED 615 emits light despite disabling the fourth LED 625. In such an example, the first detection circuitry 670 fails to detect the first parasitic resistance 630 (e.g., the first parasitic resistance 630 is not present) and the second detection circuitry 675 detects the second parasitic resistance 635. Advantageously, the controller circuitry 680 disables the second switch 650 based on an individual detection of either of the parasitic resistances 630 and 635. Advantageously, the second LED 615 may continue to emit light despite the second parasitic resistance 635 being present. Advantageously, the fourth LED 625 may continue to emit light despite the first parasitic resistance 630 being present.

The controller circuitry 680 generates the third LED on fault signal based on the first fault detection signal from the first detection circuitry 670 and durations that the LEDs 610 and/or 615 are to emit light. The controller circuitry 680 sets the third LED on fault signal to disable the LEDs 610 and 615 responsive to the first fault detection signal indicating a detection of the first parasitic resistance 630. For example, the controller circuitry 680 allows the third LED on fault signal to close the third switch 655 for durations where the LEDs 610 and/or 615 are to emit light despite disabling the LEDs 620 and 625. In such an example, the first detection circuitry 670 fails to detect the first parasitic resistance 630 (e.g., the first parasitic resistance 630 is not present) and the second detection circuitry 675 detects the second parasitic resistance 635. Advantageously, the controller circuitry 680 disables the third switch 655 based on a detection of the first parasitic resistance 630. Advantageously, the LEDs 610 and 615 may continue to emit light despite the second parasitic resistance 635 being present.

The controller circuitry 680 generates the fourth LED on fault signal based on the second fault detection signal from the second detection circuitry 675 and durations that the LEDs 620 and/or 625 are to emit light. The controller circuitry 680 sets the fourth LED on fault signal to disable the LEDs 620 and 625 responsive to the second fault detection signal indicating a detection of the second parasitic resistance 635. For example, the controller circuitry 680 allows the fourth LED on fault signal to close the fourth switch 660 for durations where the LEDs 620 and/or 625 are to emit light despite disabling the LEDs 610 and 615. In such an example, the first detection circuitry 670 detects the first parasitic resistance 630 and the second detection circuitry 675 fails to detect the second parasitic resistance 635 (e.g., the second parasitic resistance 635 is not present). Advantageously, the controller circuitry 680 disables the fourth switch 660 based on a detection of the second parasitic resistance 635. Advantageously, the LEDs 620 and 625 may continue to emit light despite the first parasitic resistance 630 being present.

The controller circuitry 680 supplies the first LED off effective signal to the first detection circuitry 670. The controller circuitry 680 generates the first LED off effective signal as an inverse of the durations that the LEDs 610 and/or 615 are to emit light. For example, the controller circuitry 680 sets the first LED off effective signal to a logic low responsive to the LEDs 610 and 615 being off (e.g., not emitting light). In some examples, the controller circuitry 680 may delay rising edges of the first LED off effective signal to account for settling times of the switches 645-655. In such examples, the controller circuitry 680 may decrease a duty cycle of the first LED off effective signal to prevent overlap with the third LED on fault signal.

The controller circuitry 680 supplies the second LED off effective signal to the second detection circuitry 675. The controller circuitry 680 generates the second LED off effective signal as an inverse of the durations that the LEDs 620 and/or 625 are to emit light. For example, the controller circuitry 680 sets the second LED off effective signal to a logic low responsive to the LEDs 620 and 625 being off (e.g., not emitting light). In some examples, the controller circuitry 680 may delay rising edges of the second LED off effective signal to account for settling times of the switches 645, 650, and 660. In such examples, the controller circuitry 680 may decrease a duty cycle of the second LED off effective signal to prevent overlap with the fourth LED on fault signal.

The controller circuitry 680 receives the first fault detection signal from the first detection circuitry 670. The controller circuitry 680 prevents the first and third LED on fault signals from changing logic states to turn on the LEDs 610 and 615 responsive to the first fault detection signal being set by the first detection circuitry 670. In such examples, the controller circuitry 680 keeps the third switch 655 open and prevents the first switch 645 from coupling the supply voltage of the voltage supply terminal 640 to the first LED 610.

The controller circuitry 680 receives the second fault detection signal from the second detection circuitry 675. The controller circuitry 680 prevents the second and fourth LED on fault signals from changing logic states to turn on the LEDs 620 and 625 responsive to the second fault detection signal being set by the second detection circuitry 675. In such examples, the controller circuitry 680 keeps the fourth switch 660 open and prevents the first switch 645 from coupling the supply voltage of the voltage supply terminal 640 to the first LED 610.

FIG. 7 is a flowchart representative of example machine readable instructions and/or example operations 700 that may be executed, instantiated, and/or performed to implement the driver circuitry 120 of FIGS. 1 and 2 to detect a formation of parasitic resistances. The example machine-readable instructions and/or the example operations 700 of FIG. 7 begin at Block 710, at which the controller circuitry 270 of FIGS. 2 and 4 closes a first switch and a second switch. In some examples, the controller circuitry 270 closes the switches 230 and 240 of FIG. 2.

The current source circuitry 250 of FIG. 2 sources a current through an LED, the anode switch, and the cathode switch. (Block 720). In some examples, the current source circuitry 250 sources a current from the voltage supply terminal 220 of FIG. 2 responsive to the switches 230 and 240 creating a current path through the LED 125 of FIGS. 1 and 2. In such examples, the LED 125 emits light responsive to the current source circuitry 250 sourcing a current through the LED 125 and the switches 230 and 240.

The controller circuitry 270 opens the first switch and the second switch. (Block 730). In some examples, the controller circuitry 270 opens the switches 230 and 240. In such examples, opening the switches 230 and 240 prevents the current source circuitry 250 from sourcing a current through the LED 125.

The detection circuitry 260 of FIGS. 2 and 3 pulls up the second switch. (Block 740). In some examples, the controller circuitry 270 closes the switch 330 of FIG. 3 to couple the current source circuitry 320 of FIG. 3 to the first terminal of the second switch 240. In such examples, the current source circuitry 320 pulls up the first terminal of the second switch 240 to approximately the voltage supply terminal 310 of FIG. 3 when the parasitic resistance 210 of FIG. 2 is not present.

The comparator 340 of FIG. 3 determines if a voltage of the second switch is less than a threshold voltage. (Block 750). In some examples, the comparator 340 compares the voltage of the first terminal of the second switch 240 to the threshold voltage VTH of the threshold voltage terminal 350 of FIG. 3. If the comparator 340 determines that the voltage of the second switch is not less than the threshold voltage (e.g., Block 750 returns a result of NO), control proceeds to return to Block 710.

If the comparator 340 determines that the voltage of the second switch is less than the threshold voltage (e.g., Block 750 returns a result of YES), the controller circuitry 270 disables the first switch and the second switch. (Block 760). In some examples, the controller circuitry 270 keeps the switches 230 and 240 open responsive to the output of the comparator 340 setting the fault detection signal 540. Control proceeds to end.

Although example processes are described with reference to the flowchart illustrated in FIG. 7, many other methods of implementing the driver circuitry 120 of FIGS. 1 and 2 may alternatively be used in accordance with teachings of this description. For example, the order of execution of the blocks may be changed, and/or some of the blocks described may be changed, eliminated, or combined. Similarly, additional operations may be included in the manufacturing process before, in between, or after the blocks shown in the illustrated examples.

While an example manner of implementing the controller circuitry 270 of FIG. 2 is illustrated in FIG. 4, one or more of the elements, processes, and/or devices illustrated in FIG. 4 may be combined, divided, re-arranged, omitted, eliminated, and/or implemented in any other way, such as in the controller circuitry 680 of FIG. 6. Further, the timing circuitry 410 of FIG. 4, the duty cycle monitor circuitry 420 of FIG. 4, the inverter 430 of FIG. 4, the detection monitor circuitry 440 of FIG. 4, and/or, more generally, the example controller circuitry 270 of FIGS. 2 and 4 and/or the controller circuitry 680 of FIG. 6, may be implemented by hardware alone or by hardware in combination with software and/or firmware. Thus, for example, any of the timing circuitry 410 of FIG. 4, the duty cycle monitor circuitry 420 of FIG. 4, the inverter 430 of FIG. 4, the detection monitor circuitry 440 of FIG. 4, and/or, more generally, the example controller circuitries 270 or 680, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)). ASIC(s), programmable logic device(s) (PLD(s)), and/or field programmable logic device(s) (FPLD(s)) such as FPGAs. Further still, the example controller circuitries 270 and/or 680 of FIGS. 2, 4, and 6 may include one or more elements, processes, and/or devices in addition to, or instead of, those illustrated in FIG. 4, and/or may include more than one of any or all of the illustrated elements, processes and devices.

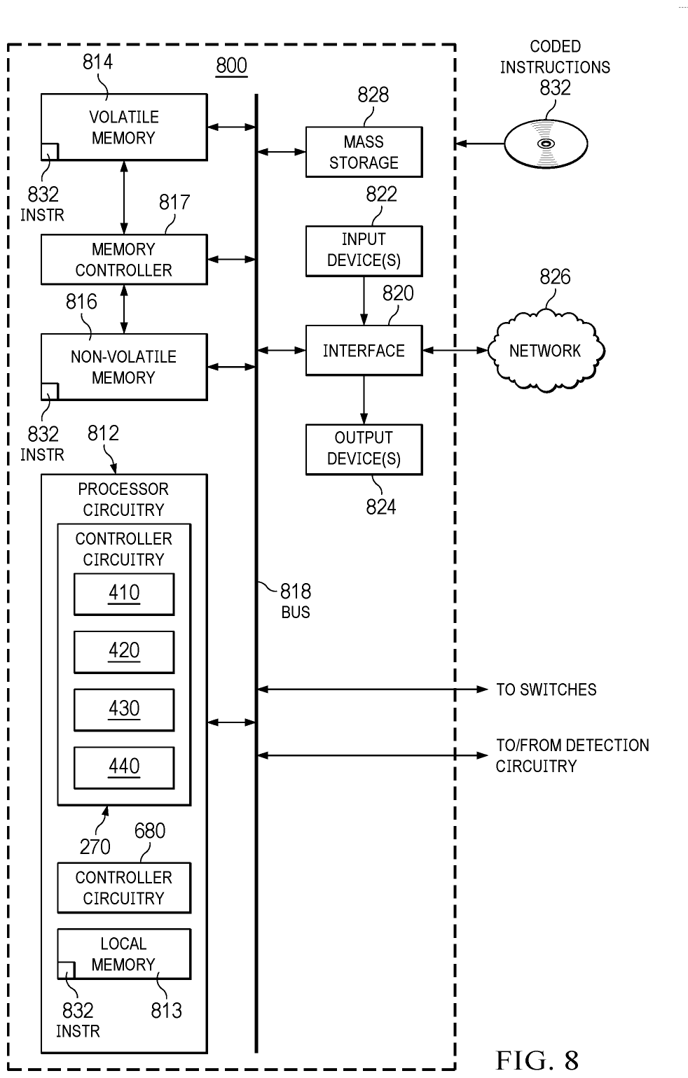

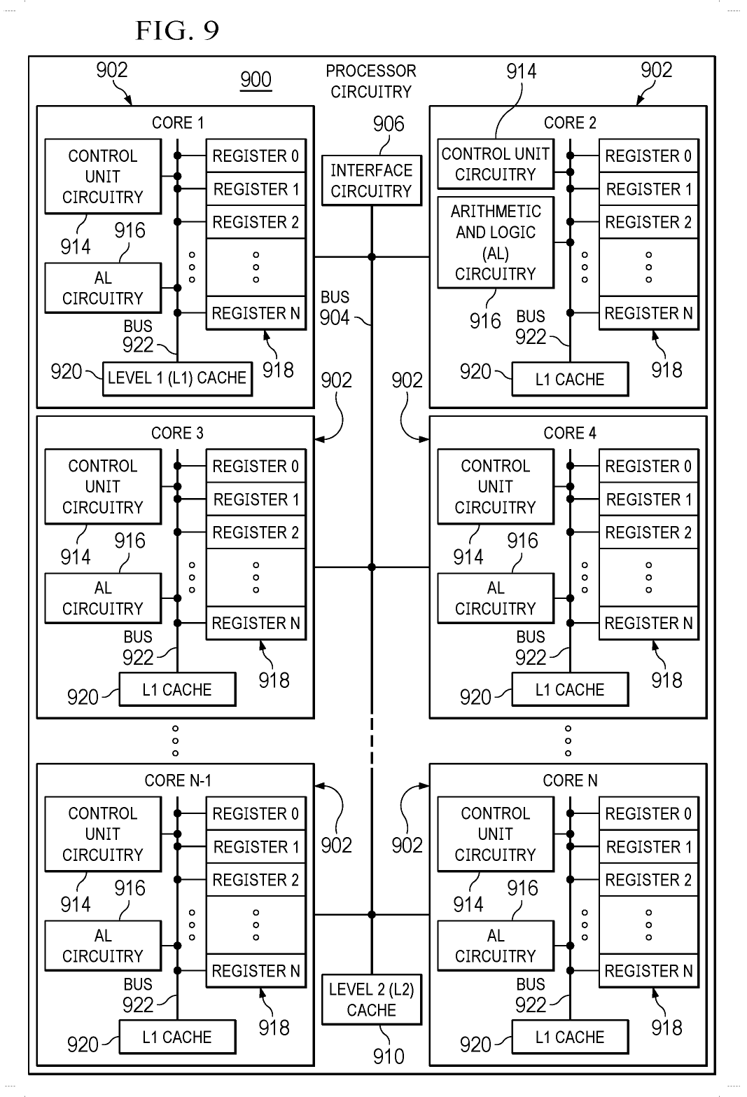

Flowchart(s) representative of example machine readable instructions, which may be executed by programmable circuitry to implement and/or instantiate the controller circuitries 270 and/or 680 of FIGS. 2, 4, and 6 and/or representative of example operations which may be performed by programmable circuitry to implement and/or instantiate the controller circuitries 270 and/or 680 of FIGS. 2, 4, and 6, are shown in FIG. 7. The machine readable instructions may be one or more executable programs or portion(s) of one or more executable programs for execution by programmable circuitry such as the programmable circuitry 812 shown in the example processor platform 800 described below in connection with FIG. 8 and/or may be one or more function(s) or portion(s) of functions to be performed by the example programmable circuitry (e.g., an FPGA) described below in connection with FIGS. 9 and/or 10. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 7, many other methods of implementing the controller circuitries 270 and/or 680 of FIGS. 2, 4, and 6 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 7 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B. (5) A with C. (6) B with C, or (7) A with B and with C. As used herein in the context of describing structures, components, items, objects and/or things, the phrase “at least one of A and B” is intended to refer to implementations including any of (1) at least one A. (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A. (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A. (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 8 is a block diagram of an example programmable circuitry platform 800 structured to execute and/or instantiate the example machine-readable instructions and/or the example operations of FIG. 7 to implement the controller circuitries 270 and/or 680 of FIGS. 2, 4, and 6. The programmable circuitry platform 800 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 800 of the illustrated example includes programmable circuitry 812. The programmable circuitry 812 of the illustrated example is hardware. For example, the programmable circuitry 812 can be implemented by one or more integrated circuits, logic circuits, FPGAs, microprocessors, CPUs, GPUs, DSPs, and/or microcontrollers from any desired family or manufacturer. The programmable circuitry 812 may be implemented by one or more semiconductor based (e.g., silicon based) devices. In this example, the programmable circuitry 812 implements the timing circuitry 410 of FIG. 4, the duty cycle monitor circuitry 420 of FIG. 4, the inverter 430 of FIG. 4, the detection monitor circuitry 440 of FIG. 4, and/or more generally the controller circuitries 270 and/or 680 of FIGS. 2, 4, and 6.

The programmable circuitry 812 of the illustrated example includes a local memory 813 (e.g., a cache, registers, etc.). The programmable circuitry 812 of the illustrated example is in communication with main memory 814, 816, which includes a volatile memory 814 and a non-volatile memory 816, by a bus 818. The volatile memory 814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 816 may be implemented by flash memory and/or any other desired type of memory device. Access to the main memory 814, 816 of the illustrated example is controlled by a memory controller 817. In some examples, the memory controller 817 may be implemented by one or more integrated circuits, logic circuits, microcontrollers from any desired family or manufacturer, or any other type of circuitry to manage the flow of data going to and from the main memory 814, 816.

The programmable circuitry platform 800 of the illustrated example also includes interface circuitry 820. The interface circuitry 820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 822 are connected to the interface circuitry 820. The input device(s) 822 permit(s) a user (e.g., a human user, a machine user, etc.) to enter data and/or commands into the programmable circuitry 812. The input device(s) 822 can be implemented by, for example, an audio sensor, a microphone, a camera (still or video), a keyboard, a button, a mouse, a touchscreen, a trackpad, a trackball, an isopoint device, and/or a voice recognition system.

One or more output devices 824 are also connected to the interface circuitry 820 of the illustrated example. The output device(s) 824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 820 of the illustrated example, thus, typically includes a graphics driver card, a graphics driver chip, and/or graphics processor circuitry such as a GPU.

The interface circuitry 820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 826. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 800 of the illustrated example also includes one or more mass storage discs or devices 828 to store firmware, software, and/or data. Examples of such mass storage discs or devices 828 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 832, which may be implemented by the machine readable instructions of FIG. 7, may be stored in the mass storage device 828, in the volatile memory 814, in the non-volatile memory 816, and/or on at least one non-transitory computer readable storage medium such as a CD or DVD which may be removable.

FIG. 9 is a block diagram of an example implementation of the programmable circuitry 812 of FIG. 8. In this example, the programmable circuitry 812 of FIG. 8 is implemented by a microprocessor 900. For example, the microprocessor 900 may be a general-purpose microprocessor (e.g., general-purpose microprocessor circuitry). The microprocessor 900 executes some or all of the machine-readable instructions of the flowchart of FIG. 7 to effectively instantiate the circuitry of FIGS. 2, 4, and/or 6 as logic circuits to perform operations corresponding to those machine readable instructions. In some such examples, the circuitry of FIGS. 2, 4, and/or 6 is instantiated by the hardware circuits of the microprocessor 900 in combination with the machine-readable instructions. For example, the microprocessor 900 may be implemented by multi-core hardware circuitry such as a CPU, a DSP, a GPU, an XPU, etc. Although it may include any number of example cores 902 (e.g., 1 core), the microprocessor 900 of this example is a multi-core semiconductor device including N cores. The cores 902 of the microprocessor 900 may operate independently or may cooperate to execute machine readable instructions. For example, machine code corresponding to a firmware program, an embedded software program, or a software program may be executed by one of the cores 902 or may be executed by multiple ones of the cores 902 at the same or different times. In some examples, the machine code corresponding to the firmware program, the embedded software program, or the software program is split into threads and executed in parallel by two or more of the cores 902. The software program may correspond to a portion or all of the machine readable instructions and/or operations represented by the flowchart of FIG. 7.

The cores 902 may communicate by a first example bus 904. In some examples, the first bus 904 may be implemented by a communication bus to effectuate communication associated with one(s) of the cores 902. For example, the first bus 904 may be implemented by at least one of an Inter-Integrated Circuit (I2C) bus, a Serial Peripheral Interface (SPI) bus, a PCI bus, or a PCIe bus. Additionally or alternatively, the first bus 904 may be implemented by any other type of computing or electrical bus. The cores 902 may obtain data, instructions, and/or signals from one or more external devices by example interface circuitry 906. The cores 902 may output data, instructions, and/or signals to the one or more external devices by the interface circuitry 906. Although the cores 902 of this example include example local memory 920 (e.g., Level 1 (L1) cache that may be split into an L1 data cache and an L1 instruction cache), the microprocessor 900 also includes example shared memory 910 that may be shared by the cores (e.g., Level 2 (L2 cache)) for high-speed access to data and/or instructions. Data and/or instructions may be transferred (e.g., shared) by writing to and/or reading from the shared memory 910. The local memory 920 of each of the cores 902 and the shared memory 910 may be part of a hierarchy of storage devices including multiple levels of cache memory and the main memory (e.g., the main memory 814, 816 of FIG. 8). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 902 may be referred to as a CPU, DSP. GPU, etc., or any other type of hardware circuitry. Each core 902 includes control unit circuitry 914, arithmetic and logic (AL) circuitry (sometimes referred to as an ALU) 916, a plurality of registers 918, the local memory 920, and a second example bus 922. Other structures may be present. For example, each core 902 may include vector unit circuitry, single instruction multiple data (SIMD) unit circuitry, load/store unit (LSU) circuitry, branch/jump unit circuitry, floating-point unit (FPU) circuitry, etc. The control unit circuitry 914 includes semiconductor-based circuits structured to control (e.g., coordinate) data movement within the corresponding core 902. The AL circuitry 916 includes semiconductor-based circuits structured to perform one or more mathematic and/or logic operations on the data within the corresponding core 902. The AL circuitry 916 of some examples performs integer based operations. In other examples, the AL circuitry 916 also performs floating-point operations. In yet other examples, the AL circuitry 916 may include first AL circuitry that performs integer-based operations and second AL circuitry that performs floating-point operations. In some examples, the AL circuitry 916 may be referred to as an Arithmetic Logic Unit (ALU).

The registers 918 are semiconductor-based structures to store data and/or instructions such as results of one or more of the operations performed by the AL circuitry 916 of the corresponding core 902. For example, the registers 918 may include vector register(s), SIMD register(s), general-purpose register(s), flag register(s), segment register(s), machine-specific register(s), instruction pointer register(s), control register(s), debug register(s), memory management register(s), machine check register(s), etc. The registers 918 may be arranged in a bank as shown in FIG. 9. Alternatively, the registers 918 may be organized in any other arrangement, format, or structure, such as by being distributed throughout the core 902 to shorten access time. The second bus 922 may be implemented by at least one of an I2C bus, a SPI bus, a PCI bus, or a PCIe bus.

Each core 902 and/or, more generally, the microprocessor 900 may include additional and/or alternative structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 900 is a semiconductor device fabricated to include many transistors interconnected to implement the structures described above in one or more integrated circuits (ICs) contained in one or more packages.

The microprocessor 900 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those described herein. A GPU, DSP and/or other programmable device can also be an accelerator. Accelerators may be on-board the microprocessor 900, in the same chip package as the microprocessor 900 and/or in one or more separate packages from the microprocessor 900.

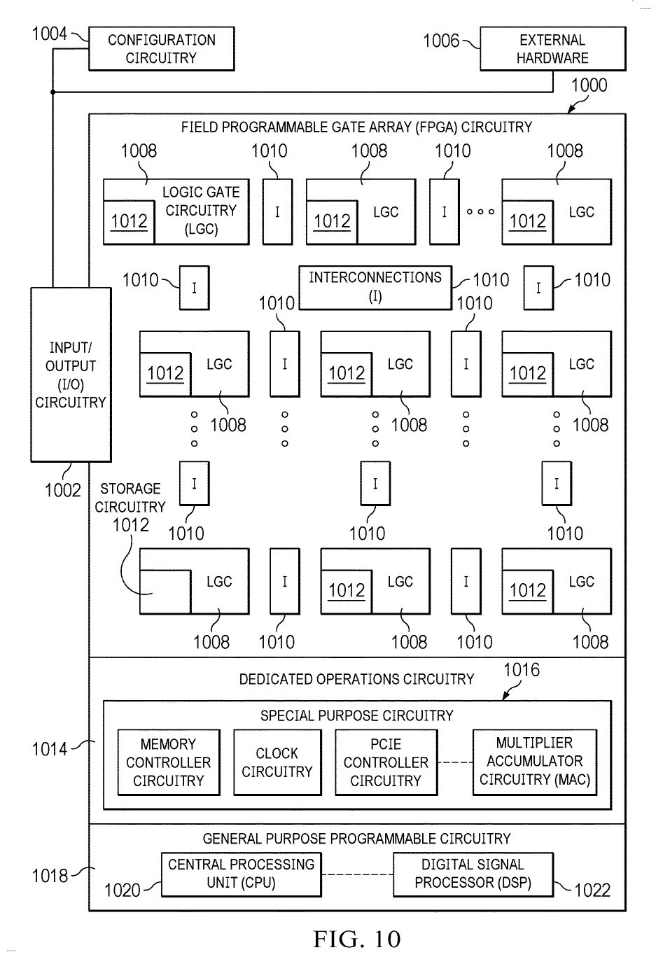

FIG. 10 is a block diagram of another example implementation of the programmable circuitry 812 of FIG. 8. In this example, the programmable circuitry 812 is implemented by FPGA circuitry 1000. For example, the FPGA circuitry 1000 may be implemented by an FPGA. The FPGA circuitry 1000 can be used, for example, to perform operations that could otherwise be performed by the example microprocessor 900 of FIG. 9 executing corresponding machine readable instructions. However, once configured, the FPGA circuitry 1000 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 900 of FIG. 9 described above (which is a general purpose device that may be programmed to execute some or all of the machine readable instructions represented by the flowchart of FIG. 7 but whose interconnections and logic circuitry are fixed once fabricated), the FPGA circuitry 1000 of the example of FIG. 10 includes interconnections and logic circuitry that may be configured, structured, programmed, and/or interconnected in different ways after fabrication to instantiate, for example, some or all of the operations/functions corresponding to the machine readable instructions represented by the flowchart of FIG. 7. In particular, the FPGA circuitry 1000 may be thought of as an array of logic gates, interconnections, and switches. The switches can be programmed to change how the logic gates are interconnected by the interconnections, effectively forming one or more dedicated logic circuits (unless and until the FPGA circuitry 1000 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 7. As such, the FPGA circuitry 1000 may be configured and/or structured to effectively instantiate some or all of the operations/functions corresponding to the machine readable instructions of the flowchart of FIG. 7 as dedicated logic circuits to perform the operations/functions corresponding to those software instructions in a dedicated manner analogous to an ASIC. Therefore, the FPGA circuitry 1000 may perform the operations/functions corresponding to the some or all of the machine readable instructions of FIG. 7 faster than the general-purpose microprocessor can execute the same.

In the example of FIG. 10, the FPGA circuitry 1000 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1000 of FIG. 10 may access and/or load the binary file to cause the FPGA circuitry 1000 of FIG. 10 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1000 of FIG. 10 to cause configuration and/or structuring of the FPGA circuitry 1000 of FIG. 10, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1000 of FIG. 10 may access and/or load the binary file to cause the FPGA circuitry 1000 of FIG. 10 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1000 of FIG. 10 to cause configuration and/or structuring of the FPGA circuitry 1000 of FIG. 10, or portion(s) thereof.

The FPGA circuitry 1000 of FIG. 10, includes example input/output (I/O) circuitry 1002 to obtain and/or output data to/from example configuration circuitry 1004 and/or external hardware 1006. For example, the configuration circuitry 1004 may be implemented by interface circuitry that may obtain a binary file, which may be implemented by a bit stream, data, and/or machine-readable instructions, to configure the FPGA circuitry 1000, or portion(s) thereof. In some such examples, the configuration circuitry 1004 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1006 may be implemented by external hardware circuitry. For example, the external hardware 1006 may be implemented by the microprocessor 900 of FIG. 9.

The FPGA circuitry 1000 also includes an array of example logic gate circuitry 1008, a plurality of example configurable interconnections 1010, and example storage circuitry 1012. The logic gate circuitry 1008 and the configurable interconnections 1010 are configurable to instantiate one or more operations/functions that may correspond to at least some of the machine readable instructions of FIG. 7 and/or other desired operations. The logic gate circuitry 1008 shown in FIG. 10 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1008 to enable configuration of the electrical structures and/or the logic gates to form circuits to perform desired operations/functions. The logic gate circuitry 1008 may include other electrical structures such as look-up tables (LUTs), registers (e.g., flip-flops or latches), multiplexers, etc.

The configurable interconnections 1010 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1008 to program desired logic circuits.

The storage circuitry 1012 of the illustrated example is structured to store result(s) of the one or more of the operations performed by corresponding logic gates. The storage circuitry 1012 may be implemented by registers or the like. In the illustrated example, the storage circuitry 1012 is distributed amongst the logic gate circuitry 1008 to facilitate access and increase execution speed.

The example FPGA circuitry 1000 of FIG. 10 also includes example dedicated operations circuitry 1014. In this example, the dedicated operations circuitry 1014 includes special purpose circuitry 1016 that may be invoked to implement commonly used functions to avoid the need to program those functions in the field. Examples of such special purpose circuitry 1016 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1000 may also include example general purpose programmable circuitry 1018 such as an example CPU 1020 and/or an example DSP 1022. Other general purpose programmable circuitry 1018 may additionally or alternatively be present such as a GPU, an XPU, etc., that can be programmed to perform other operations.

Although FIGS. 9 and 10 illustrate two example implementations of the programmable circuitry 812 of FIG. 8, many other approaches are contemplated. For example, FPGA circuitry may include an on-board CPU, such as one or more of the example CPU 1020 of FIG. 9. Therefore, the programmable circuitry 812 of FIG. 8 may additionally be implemented by combining at least the example microprocessor 900 of FIG. 9 and the example FPGA circuitry 1000 of FIG. 10. In some such hybrid examples, one or more cores 902 of FIG. 9 may execute a first portion of the machine readable instructions represented by the flowchart(s) of FIGS. [Flowcharts] to perform first operation(s)/function(s), the FPGA circuitry 1000 of FIG. 10 may be configured and/or structured to perform second operation(s)/function(s) corresponding to a second portion of the machine readable instructions represented by the flowchart of FIG. 7, and/or an ASIC may be configured and/or structured to perform third operation(s)/function(s) corresponding to a third portion of the machine readable instructions represented by the flowchart of FIG. 7.

It should be understood that some or all of the circuitry of FIG. [ER-Diagram] may, thus, be instantiated at the same or different times. For example, same and/or different portion(s) of the microprocessor 900 of FIG. 9 may be programmed to execute portion(s) of machine-readable instructions at the same and/or different times. In some examples, same and/or different portion(s) of the FPGA circuitry 1000 of FIG. 10 may be configured and/or structured to perform operations/functions corresponding to portion(s) of machine-readable instructions at the same and/or different times.

In some examples, some or all of the circuitry of FIGS. 2, 4, and/or 6 may be instantiated, for example, in one or more threads executing concurrently and/or in series. For example, the microprocessor 900 of FIG. 9 may execute machine readable instructions in one or more threads executing concurrently and/or in series. In some examples, the FPGA circuitry 1000 of FIG. 10 may be configured and/or structured to carry out operations/functions concurrently and/or in series. Moreover, in some examples, some or all of the circuitry of FIG. 4 may be implemented within one or more virtual machines and/or containers executing on the microprocessor 900 of FIG. 9.

In some examples, the programmable circuitry 812 of FIG. 8 may be in one or more packages. For example, the microprocessor 900 of FIG. 9 and/or the FPGA circuitry 1000 of FIG. 10 may be in one or more packages. In some examples, an XPU may be implemented by the programmable circuitry 812 of FIG. 8, which may be in one or more packages. For example, the XPU may include a CPU (e.g., the microprocessor 900 of FIG. 9, the CPU 1020 of FIG. 10, etc.) in one package, a DSP (e.g., the DSP 1022 of FIG. 10) in another package, a GPU in yet another package, and an FPGA (e.g., the FPGA circuitry 1000 of FIG. 10) in still yet another package.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description, do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that detect the formation of parasitic resistances using driver circuitry. Described systems, apparatus, articles of manufacture, and methods improve the efficiency of using a computing device by reducing power consumption responsive to detecting a formation of a parasitic resistance using driver circuitry. Described systems, apparatus, articles of manufacture, and methods are accordingly directed to one or more improvement(s) in the operation of a machine such as a computer or other electronic and/or mechanical device.

What is claimed is:

1. An apparatus comprising:
a first switch having a control terminal;
a second switch having a first terminal and a control terminal;
detection circuitry having a first terminal and a second terminal the detection circuitry configured to detect a parasitic resistance at the first terminal of the second switch; and
controller circuitry having a first terminal and a second terminal, the first terminal of the controller circuitry coupled to the control terminal of the first switch and the control terminal of the second switch, the second terminal of the controller circuitry coupled to second terminal of the detection circuitry, the controller circuitry configured to disable the first switch and second switch responsive to the detection of the parasitic resistance.

2. The apparatus of claim 1, wherein the first switch further includes a first terminal, the apparatus further comprising a light emitting diode (LED) having a first terminal and a second terminal, the first terminal of the LED coupled to the second terminal of the first switch, the second terminal of the LED coupled to the first terminal of the second switch and the first terminal of the detection circuitry.

3. The apparatus of claim 1, wherein the second switch further includes a second terminal, the apparatus further comprising current source circuitry having a first terminal and a second terminal, the first terminal of the current source circuitry coupled to the second terminal of the second switch, the second terminal of the current source circuitry coupled to a common potential.

4. The apparatus of claim 1, wherein the controller circuitry further includes a third terminal, the detection circuitry including:
a third switch having a first terminal, a second terminal, and a control terminal, the control terminal of the third switch coupled to the third terminal of the controller circuitry;
current source circuitry having a terminal, the terminal of the current source circuitry coupled to the first terminal of the third switch; and
a comparator having an input and an output, the input of the comparator coupled to the first terminal of the second switch and the second terminal of the third switch, the output of the comparator coupled to the second terminal of the controller circuitry.

5. The apparatus of claim 1, wherein the detection circuitry is configured to:
pull-up the first terminal the second switch;
compare a voltage of the first terminal of the second switch to a threshold voltage; and
detect the parasitic resistance based on the voltage of the first terminal of the second switch and the threshold voltage.

6. The apparatus of claim 1, wherein the controller circuitry includes:
timing circuitry having a terminal;
duty cycle monitor circuitry having a first terminal and a second terminal, the first terminal of the duty cycle monitor circuitry coupled to the terminal of the timing circuitry; and
detection monitor circuitry having a first terminal, a second terminal, and a third terminal, the first terminal of the detection monitor circuitry coupled to the second terminal of the duty cycle monitor circuitry, the second terminal of the detection monitor circuitry coupled to the second terminal of the detection circuitry, the third terminal of the detection monitor circuitry coupled to the control terminal of the first switch and the control terminal of the second switch.

7. The apparatus of claim 1, wherein the controller circuitry is configured to:
control the first switch;
control the second switch; and
when the detection circuitry detects the parasitic resistance, disable the first switch and the second switch.

8. A system comprising:
a switch having a terminal;
a light emitting diode (LED) having a first terminal and a second terminal, the first terminal of the LED coupled to the terminal of the switch; and
detection circuitry having a terminal coupled to the second terminal of the LED, the detection circuitry configured to detect a parasitic resistance at the second terminal of the LED.

9. The system of claim 8, wherein the switch is a first switch, further comprising:
a second switch having a first terminal and a second terminal, the first terminal of the second switch coupled to the second terminal of the LED and the terminal of the detection circuitry; and
current source circuitry having a first terminal and a second terminal, the first terminal of the current source circuitry coupled to the second terminal of the second switch, the second terminal of the current source circuitry coupled to a common potential.

10. The system of claim 8, wherein the switch is a first switch, the detection circuitry including:
a second switch having a first terminal and a second terminal, the first terminal of the second switch coupled to the second terminal of the LED;
current source circuitry having a terminal coupled to the second terminal of the second switch; and
a comparator having an input coupled to the second terminal of the LED and the first terminal of the second switch.

11. The system of claim 8, wherein the detection circuitry is configured to:
pull-up the second terminal of the LED;
determine a voltage of the second terminal of the LED; and
detect the parasitic resistance based on a comparison of the voltage of the second terminal of the LED to a threshold voltage.

12. The system of claim 8, wherein the switch further has a control terminal the terminal of the detection circuitry is a first terminal, the detection circuitry further having a second terminal, further including controller circuitry having a first terminal and a second terminal, the first terminal of the controller circuitry coupled to the control terminal of the switch, the second terminal of the controller circuitry coupled to the second terminal of the detection circuitry.

13. The system of claim 12, wherein the controller circuitry includes:
timing circuitry having a terminal;
duty cycle monitor circuitry having a first terminal and a second terminal, the first terminal of the duty cycle monitor circuitry coupled to the terminal of the timing circuitry; and
detection monitor circuitry having a first terminal, a second terminal, and a third terminal, the first terminal of the detection monitor circuitry coupled to the second terminal of the duty cycle monitor circuitry, the second terminal of the detection monitor circuitry coupled to the second terminal of the detection circuitry, the third terminal of the detection monitor circuitry coupled to the control terminal of the switch.

14. The system of claim 12, wherein the controller circuitry is configured to disable the switch when the detection circuitry detects a parasitic resistance at the second terminal of the LED.

15. A device comprising:
a first switch having a terminal; and
detection circuitry including:
a second switch having a first terminal and a second terminal, the first terminal of the second switch coupled to the terminal of the first switch;
current source circuitry having a first terminal and a second terminal, the first terminal of the current source circuitry coupled to the second terminal of the second switch; and
a comparator having an input coupled to the terminal of the first switch and the first terminal of the second switch.

16. The device of claim 15, further comprising a light emitting diode (LED) having a terminal, the terminal of the LED coupled to the terminal of the first switch, the first terminal of the second switch and the input of the comparator.

17. The device of claim 15, wherein the detection circuitry is configured to:
pull-up the terminal of the first switch;
determine a voltage of the terminal of the first switch; and
detect a parasitic resistance based on a comparison of the voltage of the terminal of the first switch to a threshold voltage.

18. The device of claim 15, wherein the first switch further has a control terminal, the second switch further has a control terminal, the comparator further having an output, further including controller circuitry having a first terminal, a second terminal, and a third terminal, the first terminal of the controller circuitry coupled to the control terminal of the first switch, the second terminal of the controller circuitry coupled to the control terminal of the second switch, the third terminal of the controller circuitry coupled to the output of the comparator.

19. The device of claim 18, wherein the controller circuitry includes:
timing circuitry having a terminal;
duty cycle monitor circuitry having a first terminal and a second terminal, the first terminal of the duty cycle monitor circuitry coupled to the terminal of the timing circuitry; and
detection monitor circuitry having a first terminal, a second terminal, and a third terminal, the first terminal of the detection monitor circuitry coupled to the second terminal of the duty cycle monitor circuitry, the second terminal of the detection monitor circuitry coupled to the output of the comparator, the third terminal of the detection monitor circuitry coupled to the control terminal of the first switch.

20. The device of claim 18, wherein the controller circuitry is configured to disable the first switch responsive to the detection circuitry detecting a parasitic resistance at the terminal of the first switch.
